(19) United States
(12) Patent Application Publication
(10) Pub. No.: US 2026/0066884 A1
(43) Pub. Date: Mar. 5, 2026

(54) CONNECTOR CIRCUIT, CONTROL CIRCUIT, AND SLEW RATE CONTROL CIRCUIT THEREOF

(71) Applicant: REALTEK SEMICONDUCTOR CORP., Hsinchu (TW)

(72) Inventors: Guo-Yuan Luo, Hsinchu (TW); Chien-Liang Chen, Hsinchu (TW); Chao-Min Lai, Hsinchu (TW); Jyun-Ren Chen, Hsinchu (TW)

(73) Assignee: REALTEK SEMICONDUCTOR CORP., Hsinchu (TW)

(21) Appl. No.: 19/317,480

(22) Filed: Sep. 3, 2025

(30) Foreign Application Priority Data
Sep. 5, 2024 (TW) 113133748

(51) Int. Cl. H03K 5/04; H01R 13/66

(52) U.S. Cl. CPC H03K 5/04; H01R 13/6691

(57) ABSTRACT

A slew rate control circuit includes a ground wire, a power wire, an output end, two switches, two switching circuits, and two grounding capacitors. The switches are respectively connected between the power wire and the output end and between the output end and the ground wire. The switching circuits are respectively connected between the power wire and the ground wire and controlled by two driving signals and thus inversely driven. One of the switching circuits is configured to drive one of the switches through the first resistance, and the other is configured to drive the other one of the switches through the second resistance. One of the grounding capacitors is connected to a control end of the first switch and one of the switching circuits, and the other is connected to a control end of the second switch and the other one of the switching circuits.

### CROSS-REFERENCE TO RELATED APPLICATION

This non-provisional application claims priority under 35 U.S.C. § 119 (a) to patent application No. 113133748 filed in Taiwan, R.O.C. on Sep. 5, 2024, the entire contents of which are hereby incorporated by reference.

### BACKGROUND

### Technical Field

The instant disclosure relates to a connector circuit, in particular to a connector circuit having a slew rate control circuit.

### Related Art

The I²C (inter-integrated circuit) is a common communication method between electronic devices. A driving manner for the I²C known to the inventor is controlling a level of an output signal using an open-drain configuration. Under this configuration, a low level is implemented through an internal circuit pulling low, and a high level is implemented by an external pull-up circuit which slowly pulls the level up. Therefore, a slew rate of the pulling down of the signal is very high. A high slew rate will lead to neighboring signals being interfered. For example, in a type-A high definition multimedia interface (HDMI), the I²C and an enhanced audio return channel (eARC) are adjacent pins (with a space of 0.5 millimeter). If the slew rate of the pulling down of the I²C is too high, the eARC is easily interfered.

### SUMMARY

Some methods for reducing the slew rate of the I²C known to the inventor include adding a series resistor or a grounding capacitor. However, the series resistor can affect the low level potential of the signal and possibly cause a test failure of a compliance test specification (CTS) of the HDMI. On the other hand, the grounding capacitor can increase a capacitive reactance on the signal wire and also cause the test failure of the CTS. In order to address the above issues, one method known to the inventor is to decrease the slew rate of the I²C by connecting ferrite beads in series. However, this method increases more material cost.

In some embodiments, a slew rate control circuit comprises a ground wire, a power wire, an output end, a first switch, a second switch, a first switching circuit, a second switching circuit, a first grounding capacitor, and a second grounding capacitor. The first switch is connected between the power wire and the output end. The second switch is connected between the output end and the ground wire. The first switching circuit is connected between the power wire and the ground wire, has a first resistance, is controlled by a first driving signal, and is configured to drive the first switch through the first resistance. The second switching circuit is connected between the power wire and the ground wire, has a second resistance, is controlled by a second driving signal, and is configured to drive the second switch through the second resistance. The first switching circuit and the second switching circuit are inversely driven. The first grounding capacitor is connected to a control end of the first switch and the first switching circuit. The second grounding capacitor is connected to a control end of the second switch and the second switching circuit.

In some embodiments, a control circuit comprises an ancillary signal pad, at least one high-speed signal pad, a ground pad, a power pad, a signal processing circuit, and a slew rate control circuit. The signal processing circuit is connected to the ancillary signal pad, the ground pad, and the power pad. The slew rate control circuit comprises a first switch, a second switch, a first switching circuit, a second switching circuit, a first grounding capacitor, and a second grounding capacitor. The first switch is connected between the power pad and one of the high-speed signal pad. The second switch is connected between the one of the high-speed signal pad and the ground pad. The first switching circuit is connected between the power pad and the ground pad, has a first resistance, is controlled by the first driving signal, and is configured to drive the first switch through the first resistance. The second switching circuit is connected between the power pad and the ground pad, has a second resistance, is controlled by the second driving signal, and is configured to drive the second switch through the second resistance. The first switching circuit and the second switching circuit are respectively controlled by the first driving signal and the second driving signal and thus inversely driven. The first grounding capacitor is connected to a control end of the first switch and the first switching circuit. The second grounding capacitor is connected to a control end of the second switch and the second switching circuit.

In some embodiments, a connector circuit comprises a connector, a signal processing circuit, and a slew rate control circuit. The connector comprises a connection head, at least one high-speed signal pin, an ancillary signal pin, a ground pin, and a power pin. The connection head has a mating portion. The at least one high-speed signal pin, the ancillary signal pin, the ground pin, and the power pin are on the mating portion and fixed on the connection head. The ancillary signal pin is next to the at least one high-speed signal pin. The signal processing circuit is connected to the ancillary signal pin, the ground pin, and the power pin. The slew rate control circuit comprises a first switch, a second switch, a first switching circuit, a second switching circuit, a first grounding capacitor, and a second grounding capacitor. The first switch is connected between the power pin and one of the at least one high-speed signal pin. The second switch is connected between the one of the at least one high-speed signal pin and the ground pin. The first switching circuit is connected between the power pin and the ground pin, has a first resistance, is controlled by a first driving signal, and is configured to drive the first switch through the first resistance. The second switching circuit is connected between the power pin and the ground pin, has a second resistance, is controlled by a second driving signal, and is configured to drive the second switch through the second resistance. The first grounding capacitor is connected to a control end of the first switch and the first switching circuit. The second grounding capacitor is connected to a control end of the second switch and the second switching circuit.

As above, the slew rate control circuit provided by any of the embodiments is able to suppress the slew rate of the I²C and prevent the open-drain configuration from affecting the signal level at the same time and does not need additional elements such as series resistors, grounding capacitors, and/or series ferrite beads at the output end.

### BRIEF DESCRIPTION OF THE DRAWINGS

The instant disclosure will become more fully understood from the detailed description given herein below for illustration only, and therefore not limitative of the instant disclosure, wherein:

FIG. 1 illustrates a structural diagram of a slew rate control circuit of an embodiment;

FIG. 2 illustrates a perspective view of a connector of an embodiment;

FIG. 3 illustrates a schematic view of a mating portion and pins of a connector of an embodiment;

FIG. 4 illustrates a block diagram of a connector circuit of an embodiment; and

FIG. 5 illustrates a block diagram of a multimedia device of an embodiment.

### DETAILED DESCRIPTION

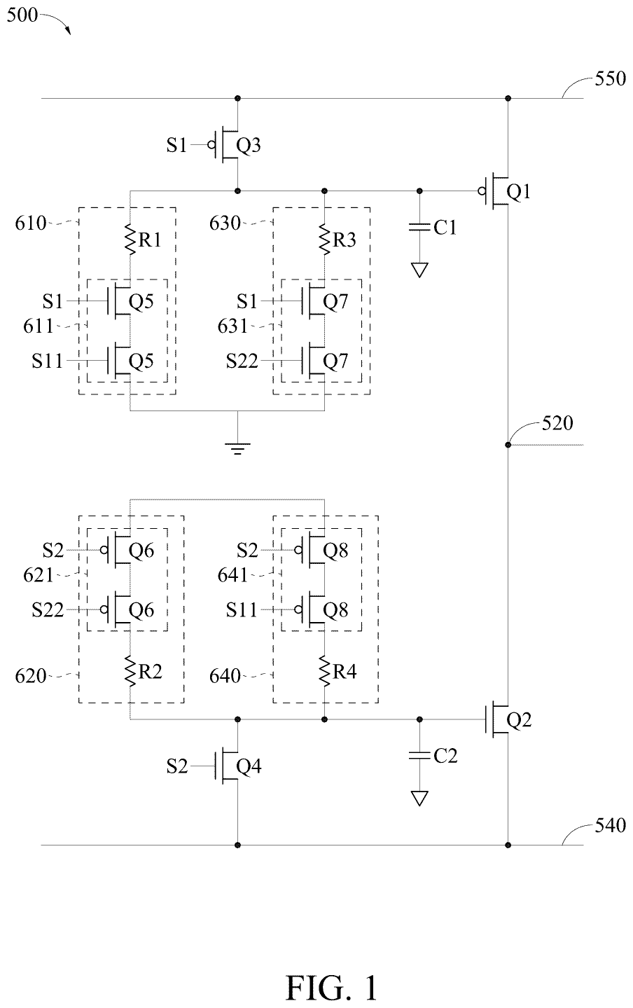

Please refer to FIG. 1. In some embodiments, a slew rate control circuit 500 comprises a ground wire 540, a power wire 550, an output end 520, two switches (referred to as a first switch Q1 and a second switch Q2 hereinafter, respectively), two switching circuits (referred to as a first switching circuit 610 and a second switching circuit 620 hereinafter, respectively), and two grounding capacitors (referred to as a first grounding capacitor C1 and a second grounding capacitor C2 hereinafter, respectively). The first switch Q1 is connected between the power wire 550 and the output end 520. The second switch Q2 is connected between the output end 520 and the ground wire 540. The first switch Q1 pulls up a potential of the output end 520 when the first switch Q1 is turned on, and the second switch Q2 pulls down the potential of the output end 520 when the second switch Q2 is turned on. In particular, in this embodiment, there is no series resistor (i.e., a pull-up resistor) between the first switch Q1 and the output end 520.

In an I²C configuration known to the inventor, the pulling up and the pulling down of an I²C pin is achieved through an open-drain configuration. under this configuration, when a switch corresponding to the first switch Q1 is turned on, the pulling up of the potential is slowly achieved by the pull-up circuit (such as a pull-up resistor, not shown in the drawings); when a switch corresponding to the second switch Q2 is turned on, the pulling down of the potential is achieved by grounding. Therefore, under this configuration, the slew rate of the pulling down of the potential is very high, and this slew rate can affect the signals on adjacent pins.

Please refer to FIG. 1. The first switching circuit 610 is connected between the power wire 550 and the ground wire 540, has a first resistance, and is configured to drive the first switch Q1 through the first resistance. The second switching circuit 620 is connected between the power wire 550 and the ground wire 540, has a second resistance, and is configured to drive the second switch Q2 through the second resistance. The first switching circuit 610 and the second switching circuit 620 are respectively controlled by a first driving signal S1 and a second driving signal S2 and thus inversely driven. The first grounding capacitor C1 is connected to a control end of the first switch Q1 and the first switching circuit 610. The second grounding capacitor C2 is connected to a control end of the second switch Q2 and the second switching circuit 620. The first resistance and the second resistance are both greater than 0. Therefore, the first resistance and the second resistance can slow down driving speeds of the first switch Q1 and the second switch Q2 and in turn decrease the slew rate of the signal level of the output end 520. In some embodiments, the first resistance equals the second resistance, but the instant disclosure is not limited thereto. In some embodiments, the first switching circuit 610 is a high active switching circuit, the second switching circuit 620 is a low active switching circuit, and the first driving signal S1 and the second driving signal S2 are synchronized signals, but the instant disclosure is not limited thereto. As long as the first switching circuit 610 and the second switching circuit 620 can be inversely driven, whether the first switching circuit 610 and the second switching circuit 620 each are the high active type or the low active type and what signals the first switching circuit 610 and the second switching circuit 620 receive are not limited.

Please refer to FIG. 1. In some embodiments, the first switching circuit 610 comprises a first path switch 611 and a first resistive element R1, and the second switching circuit 620 comprises a second path switch 621 and a second resistive element R2. The first path switch 611 is controlled by the first driving signal S1, and the first path switch 611 is connected between the power wire 550 and the ground wire 540. The first resistive element R1 is configured to provide the first resistance and connected to the first path switch 611 in series. The second path switch 621 is controlled by the second driving signal S2, and the second path switch 621 is connected between the power wire 550 and the ground wire 540. The second resistive element R2 is configured to provide the second resistance and connected to the second path switch 621 in series.

Please refer to FIG. 1. In some embodiments, the slew rate control circuit 500 further comprises a third switch Q3. The third switch Q3 and the first switching circuit 610 are inversely driven, one of two ends of the third switch Q3 is connected to the power wire 550, the other end of the third switch Q3 is connected to the first switching circuit 610 and the control end of the first switch Q1, and the first switch Q1 is a low active switch. In some embodiments, the first switching circuit 610 is a high active switching circuit, the third switch Q3 is a low active switch, and the first switching circuit 610 and the third switch Q3 both receive the first driving signal S1, but the instant disclosure is not limited thereto. As long as the third switch Q3 and the first switching circuit 610 can be inversely driven, whether the third switch Q3 and the first switching circuit 610 each are the high active type or the low active type and what signal the third switch Q3 receives are not limited. As a result, when the third switch Q3 is turned on, the first switch Q1 (whose control end is at the high level in this embodiment) and the first switching circuit 610 are turned off; when the third switch Q3 is turned off, the first switch Q1 (whose control end is at the low level in this embodiment) and the first switching circuit 610 are turned on.

Please refer to FIG. 1. In some embodiments, the slew rate control circuit 500 further comprises a fourth switch Q4. The fourth switch Q4 and the second switching circuit 620 are inversely driven, one of two ends of the fourth switch Q4 is connected to the ground wire 540, the other end of the fourth switch Q4 is connected to the second switching circuit 620 and the control end of the second switch Q2, and the second switch Q2 is a high active switch. In some embodiments, the second switching circuit 620 is a low active switching circuit, the fourth switch Q4 is a high active switch, and the second switching circuit 620 and the fourth switch Q4 both receive the second driving signal S2, but the instant disclosure is not limited thereto. As long as the fourth switch Q4 and the second switching circuit 620 can be inversely driven, whether the fourth switch Q4 and the second switching circuit 620 each are the high active type or the low active type and what signal the fourth switch Q4 receives are not limited. As a result, when the fourth switch Q4 is turned on, the second switch Q2 (whose control end is at the low level in this embodiment) and the second switching circuit 620 are turned off; when the fourth switch Q4 is turned on, the second switch Q2 (whose control end is at the high level in this embodiment) and the second switching circuit 620 are turned on.

However, in some embodiments, the first switch Q1 may also be implemented using a high active switch. In this embodiment, one of two ends of the third switch Q3 is connected to the ground wire 540, and the other end of the third switch Q3 is connected to the first switching circuit 610 and the control end of the first switch Q1. As a result, when the third switch Q3 is turned on, the first switch Q1 (whose control end is at the low level in this embodiment) and the first switching circuit 610 are turned off; when the third switch Q3 is turned off, the first switch Q1 (whose control end is at the high level in this embodiment) and the first switching circuit 610 are turned on.

Likewise, in some embodiments, the second switch Q2 may also be implemented using a low active switch. In this embodiment, one of two ends of the fourth switch Q4 is connected to the power wire 550, and the other end of the fourth switch Q4 is connected to the second switching circuit 620 and the control end of the second switch Q2. As a result, when the fourth switch Q4 is turned on, the second switch Q2 (whose control end is at the high level in this embodiment) and the second switching circuit 620 are turned off; when the fourth switch Q4 is turned on, the second switch Q2 (whose control end is at the low level in this embodiment) and the second switching circuit 620 are turned on.

Please refer to FIG. 1. In some embodiments, the slew rate control circuit 500 further comprises a third switching circuit 630 and a fourth switching circuit 640. The third switching circuit 630 is connected to the first switching circuit 610 in parallel, has a third resistance, is controlled by the first driving signal S1, and is configured to drive the first switch Q1 through the third resistance. The first resistance is greater than the third resistance. The fourth switching circuit 640 is connected to the second switching circuit 620 in parallel, has a fourth resistance, is controlled by the second driving signal S2, and is configured to drive the second switch Q2 through the fourth resistance. The second resistance is greater than the fourth resistance. The first switching circuit 610 and the fourth switching circuit 640 are further controlled by a first mode signal S11. The second switching circuit 620 and the third switching circuit 630 are further controlled by a second mode signal S22. The first mode signal S11 and the second mode signal S22 are inverted signals to each other. As a result, a user can selectively turn on the third switching circuit 630 (i.e., drive the first switch Q1 through the third resistance) and turn on the fourth switching circuit 640 (i.e., drive the second switch Q2 through the fourth resistance) in some cases so as to adjust the signal level of the output end 520 with a higher slew rate. In some embodiments, the third resistance equals the fourth resistance, but the instant disclosure is not limited thereto. In some embodiments, the third resistance and the fourth resistance are both 0.

Please refer to FIG. 1. In some embodiments, the first switching circuit 610 comprises a first path switch 611 and a first resistive element R1, the second switching circuit 620 comprises a second path switch 621 and a second resistive element R2, the third switching circuit 630 comprises a third path switch 631 and a third resistive element R3, and the fourth switching circuit 640 comprises a fourth path switch 641 and a fourth resistive element R4. The first path switch 611 is controlled by the first driving signal S1 and the first mode signal S11, and the first path switch 611 is connected between the power wire 550 and the ground wire 540. The first resistive element R1 is configured to provide the first resistance and connected to the first path switch 611 in series. The second path switch 621 is controlled by the second driving signal S2 and the second mode signal S22, and the second path switch 621 is connected between the power wire 550 and the ground wire 540. The second resistive element R2 is configured to provide the second resistance and connected to the second path switch 621 in series. The third path switch 631 is controlled by the first driving signal S1 and the second mode signal S22, and the third path switch 631 is connected between the power wire 550 and the ground wire 540. The third resistive element R3 is configured to provide the third first resistance and connected to the third path switch 631 in series. The fourth path switch 641 is controlled by the second driving signal S2 and the first mode signal S11, and the fourth path switch 641 is connected between the power wire 550 and the ground wire 540. The fourth resistive element R4 is configured to provide the fourth resistance and connected to the fourth path switch 641 in series.

Continuing from the previous paragraph, in some embodiments, the first path switch 611 comprises a plurality of fifth switches Q5, the second path switch 621 comprises a plurality of sixth switches Q6, the third path switch 631 comprises a plurality of seventh switches Q7, and the fourth path switch 641 comprises a plurality of eighth switches Q8. The fifth switches Q5 are connected to the first resistive element R1 in series, and each of the fifth switches Q5 is controlled by one of the first driving signal S1 and the first mode signal S11. For example, as shown in FIG. 1, one of the fifth switches Q5 is controlled by the first driving signal S1, and the other one of the fifth switches Q5 is controlled by the first mode signal S11. As a result, when both of the fifth switches Q5 are turned on, the first path switch 611 is turned on. In different embodiments, the two fifth switches Q5 may be switches of identical or not identical types (the two high active switches in FIG. 1 are merely for illustrative purposes and not used to limit the types of the fifth switches Q5), and the number of the fifth switches Q5 may be greater than 2.

The sixth switches Q6 are connected to the second resistive element R2 in series, and each of the sixth switches Q6 is controlled by one of the second driving signal S2 and the second mode signal S22. For example, as shown in FIG. 1, one of the sixth switches Q6 is controlled by the second driving signal S2, and the other one of the sixth switches Q6 is controlled by the second mode signal S22. As a result, when both of the sixth switches Q6 are turned on, the second path switch 621 is turned on. In different embodiments, the two sixth switches Q6 may be switches of identical or not identical types (the low active switches in FIG. 1 are merely for illustrative purposes and not used to limit the types of the sixth switches Q6), and the number of the sixth switches Q6 may be greater than 2.

The seventh switches Q7 are connected to the third resistive element R3 in series, and each of the seventh switches Q7 is controlled by one of the first driving signal S1 and the second mode signal S22. For example, as shown in FIG. 1, one of the seventh switches Q7 is controlled by the first driving signal S1, and the other one of the seventh switches Q7 is controlled by the second mode signal S22. As a result, when both of the seventh switches Q7 are turned on, the third path switch 631 is turned on. In different embodiments, the two seventh switches Q7 may be switches of identical or not identical types (the two high active switches in FIG. 1 are merely for illustrative purposes and not used to limit the types of the seventh switches Q7), and the number of the seventh switches Q7 may be greater than 2.

The eighth switches Q8 are connected to the fourth resistive element R4 in series, and each of the eighth switches Q8 is controlled by one of the second driving signal S2 and the first mode signal S11. For example, as shown in FIG. 1, one of the eighth switches Q8 is controlled by the second driving signal S2, and the other one of the eighth switches Q8 is controlled by the first mode signal S11. As a result, when both of the eighth switches Q8 are turned on, the fourth path switch 641 is turned on. In different embodiments, the two eighth switches Q8 may be switches of identical or not identical types (the low active switches in FIG. 1 are merely for illustrative purposes and not used to limit the types of the eighth switches Q8), and the number of the eighth switches Q8 may be greater than 2.

However, in some embodiments, the first switching circuit 610 and the third switching circuit 630 can be turned on separately or together to drive the first switch Q1 through the first resistance, the third resistance, or the first resistance and the third resistance in parallel. Likewise, in some embodiments, the second switching circuit 620 and the fourth switching circuit 640 can be turned on separately or together to drive the second switch Q2 through the second resistance, the fourth resistance, or the second resistance and the fourth resistance in parallel.

The switches in the above embodiments can be implemented using various types of transistors but are not limited thereto. Besides, the resistive elements in the above embodiments can be implemented using resistors but are not limited thereto.

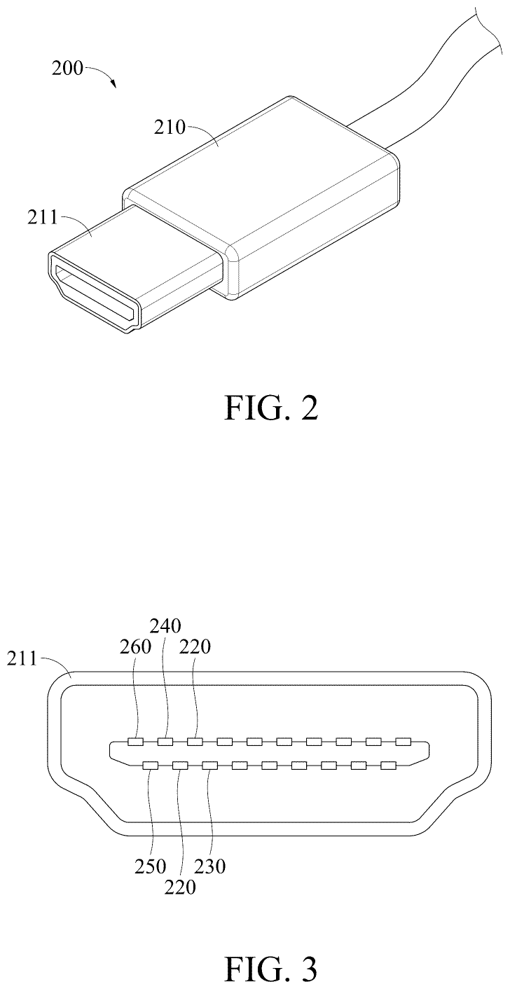

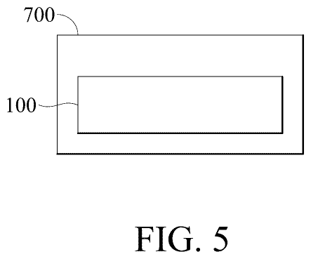

Please refer to FIG. 2 to FIG. 4. In some embodiments, a connector circuit 100 comprises a connector 200, a signal processing circuit 400, and the slew rate control circuit 500. In order to clearly illustrate, the following description will illustrate using an example where the connector 200 is a type-A high definition multimedia interface (HDMI), but the connector 200 is not limited to a type-A HDMI. In some embodiments, the connector circuit 100 further comprises a control circuit 300. The slew rate control circuit 500 of any of the above embodiments can be adopted in the control circuit 300, and the signal processing circuit 400 and the slew rate control circuit 500 can be included in the control circuit 300. In some embodiments, the connector 200 can be implemented on a multimedia device 700, such as a television, a speaker, a speaker bar, an audio/video receiver (AVR), as shown in FIG. 5. Alternatively, in some embodiments, the connector 200 can be implemented on a connection cable, as shown in FIG. 2.

Please refer to FIG. 2 to FIG. 4. A connector 200 comprises a connection head 210, at least one high-speed signal pin 220, an ancillary signal pin 230, a ground pin 240, a power pin 250, and a detection pin 260. The connection head 210 has a mating portion 211. The at least one high-speed signal pin 220, the ancillary signal pin 230, the ground pin 240, the power pin 250, and the detection pin 260 are on the mating portion 211 and fixed on the connection head 210. The ancillary signal pin 230 is adjacent to the at least one high-speed signal pin 220. In different embodiments, the connection head 210 may be a plug (as shown in FIG. 2) or a receptacle (such as on the multimedia device 700 shown in FIG. 5).

In some embodiments, the ground wire 540 is connected to the ground pin 240, the power wire 550 is connected to the power pin 250, and the output end 520 is connected to the at least one high-speed signal pin 220. The slew rate control circuit 500 is configured to control the slew rate of the signal level of the output end 520 and in turn control the slew rate of the signal level of the at least one high-speed signal pin 220.

For example, take the case that the connector 200 is a type-A HDMI as an example. The HDMI has 19 pins, as shown in FIG. 3. In this embodiment, among the 19 pins, the at least one high-speed signal pin 220 is the I²C SCL (15^{th}) pin and the I²C SDA (16^{th}) pin which may have higher slew rate and affect the signals on adjacent pins. In this embodiment, the ancillary signal pin 230 is the HEAC+/eARC+ (14^{th}) pin, and the ancillary signal pin 230 allows complete audio signals to be transmitted to an audio playing device without loss. In this embodiment, the ground pin 240 is the DDC/CEC ground (17^{th}) pin, and the ground pin 240 is adapted to be connected to a ground potential external to the slew rate control circuit 500. In this embodiment, the power pin 250 is the +5V power (18^{th}) pin, and the power pin 250 is adapted to be connected to a circuit external to the slew rate control circuit 500 and to introduce supply voltage VCC so as to provide the power for the operation of various elements. In this embodiment, the detection pin 260 is the hot plug detect/HEAC−/eARC− (19^{th}) pin, and the detection pin 260 allows the multimedia source device to detect whether the display device (such as the multimedia device 700) is connected. Because the ancillary signal pin 230 is adjacent to the high-speed signal pin 220, when the slew rate of the high-speed signal pin 220 is very high, the signal on the ancillary signal pin 230 can be affected. The signal processing circuit 400 is connected to the ancillary signal pin 230, the ground pin 240, the power pin 250, and the detection pin 260. In some embodiments, the signal processing circuit 400 processes the signals on the ancillary signal pin 230 and the signal on the detection pin 260. In some embodiments, the signal processing circuit 400 is further connected to another pin on the connector 200 and processes the signal on the additionally connected pin.

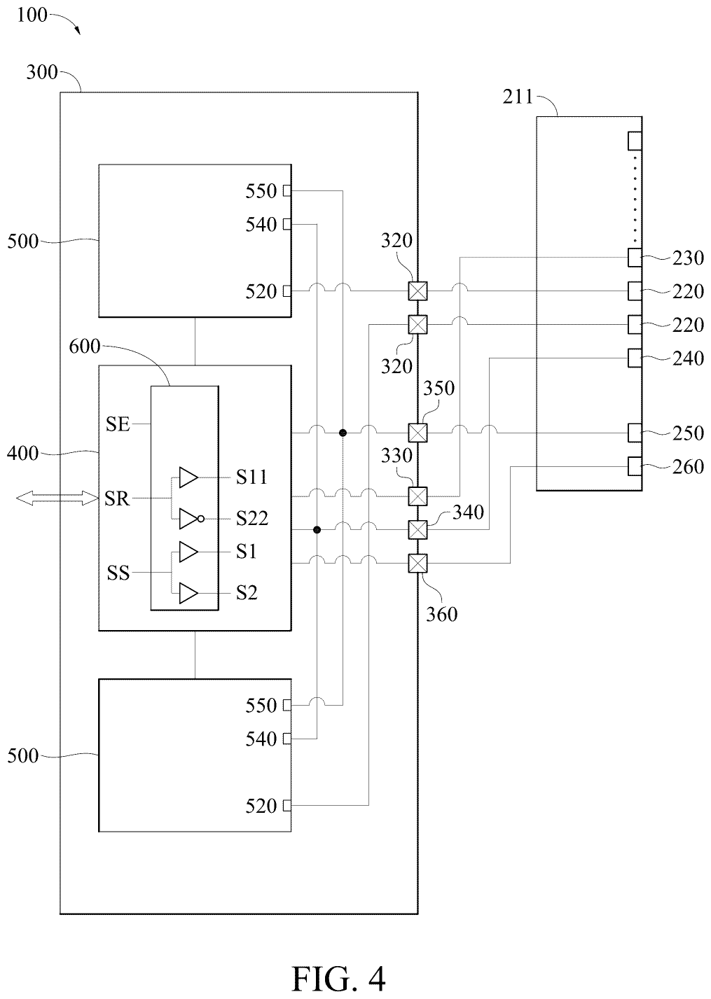

In some embodiments, the control circuit 300 further comprises an integrated circuit 600. In some embodiments, the integrated circuit 600 is integrated in the signal processing circuit 400, as shown in FIG. 4. In some embodiments, the integrated circuit 600 is independent from the signal processing circuit 4000

In some embodiments, the signal processing circuit 400 generates the first driving signal S1 and the second driving signal S2 for the slew rate control circuit 500. In some embodiments, the first driving signal S1 and the second driving signal S2 are generated by the integrated circuit 600. For example, the signal processing circuit 400 receives a turn-on signal SS and then outputs the turn-on signal SS as the first driving signal S1 and the second driving signal S2. Alternatively, in some embodiments, the integrated circuit 600 receives an enable signal SE and the turn-on signal SS and then outputs the turn-on signal SS as the first driving signal S1 and the second driving signal S2. In some embodiments, the enable signal SE and the turn-on signal SS may be set by a register (not shown in the drawings) and controlled by a digital circuit (not shown in the drawings). In some embodiments, the first driving signal S1 and the second driving signal S2 are synchronized signals obtained by buffering the turn-on signal SS, as shown in FIG. 4. However, as described before, as long as the aforementioned switching circuits and switches can be correctly driven synchronously or inversely, whether the first driving signal S1 and the second driving signal S2 are synchronized signals is not limited.

Besides, in some embodiments, the signal processing circuit 400 generates the first mode signal S11 and the second mode signal S22 for the slew rate control circuit 500. In some embodiments, the first mode signal S11 and the second mode signal S22 are generated by the integrated circuit 600. For example, the signal processing circuit 400 receives a slew rate control signal SR and then outputs the first mode signal S11 and the second mode signal S22. Alternatively, in some embodiments, the integrated circuit 600 receives the enable signal SE and the slew rate control signal SR and then outputs the first mode signal S11 and the second mode signal S22. In some embodiments, the slew rate control signal SR may be set by a register (not shown in the drawings) and controlled by a digital circuit (not shown in the drawings). In some embodiments, first mode signal S11 is obtained by buffering the slew rate control signal SR, and the second mode signal S22 is obtained by inverting the slew rate control signal SR, as shown in FIG. 4. However, as described before, as long as the aforementioned switching circuits and switches can be correctly driven synchronously or inversely, whether the first mode signal S11 and the second mode signal S22 are inverted signals is not limited.

Please refer to FIG. 1 and FIG. 4. In some embodiments, the control circuit 300 comprises a plurality of pads, the signal processing circuit 400, and the slew rate control circuit 500. In this embodiment, the control circuit 300 at least comprises an ancillary signal pad 330, at least one high-speed signal pad 320, a ground pad 340, a power pad 350, and a detection pad 360. The signal processing circuit 400 is connected to the ancillary signal pad 330, the ground pad 340, the power pad 350, and the detection pad 360. In some embodiments, the control circuit 300 may be integrated into one integrated circuit (IC).

In some embodiments, the ground wire 540 is connected to the ground pad 340, the power wire 550 is connected to the power pad 350, and the output end 520 is connected to the at least one high-speed signal pad 320. In some embodiments, the ground wire 540 is connected to the ground pin 240 through the ground pad 340, the power wire 550 is connected to the power pin 250 through the power pad 350, and the output end 520 is connected to the at least one high-speed signal pin 220 through the at least one high-speed signal pad 320.

Please refer to FIG. 1 and FIG. 4. In some embodiments, the signal processing circuit 400 and the slew rate control circuit 500 are connected to each of the pins (the at least one high-speed signal pin 220, the ancillary signal pin 230, the ground pin 240, the power pin 250, and the detection pin 260) through a corresponding one of the pads (the ancillary signal pad 330, the at least one high-speed signal pad 320, the ground pad 340, the power pad 350, and the detection pad 360).

As above, the slew rate control circuit provided by any of the embodiments is able to suppress the slew rate of the I²C and prevent the open-drain configuration from affecting the signal level at the same time and does not need additional elements such as series resistors, grounding capacitors and/or series ferrite beads at the output end.

What is claimed is:

1. A slew rate control circuit comprising:
a ground wire;
a power wire;
an output end;
a first switch connected between the power wire and the output end;
a second switch connected between the output end and the ground wire;
a first switching circuit connected between the power wire and the ground wire, wherein the first switching circuit has a first resistance, is controlled by a first driving signal, and is configured to drive the first switch through the first resistance;
a second switching circuit connected between the power wire and the ground wire, wherein the second switching circuit has a second resistance, is controlled by a second driving signal, and is configured to drive the second switch through the second resistance, and wherein the first switching circuit and the second switching circuit are inversely driven;
a first grounding capacitor connected to a control end of the first switch and the first switching circuit; and
a second grounding capacitor connected to a control end of the second switch and the second switching circuit.

2. The slew rate control circuit according to claim 1, further comprising:
a third switch, wherein the third switch and the first switching circuit are inversely driven; one of two ends of the third switch is connected to the power wire, the other end of the third switch is connected to the first switching circuit and the control end of the first switch, and the first switch is a low active switch; and
a fourth switch, wherein the fourth switch and the second switching circuit are inversely driven; one of two ends of the fourth switch is connected to the second switching circuit and the control end of the second switch, the other end of the fourth switch is connected to the ground wire, and the second switch is a high active switch.

3. The slew rate control circuit according to claim 1, further comprising:
a third switching circuit connected to the first switching circuit in parallel, wherein the third switching circuit has a third resistance, is controlled by the first driving signal, and is configured to drive the first switch through the third resistance, and wherein the first resistance is greater than the third resistance; and
a fourth switching circuit connected to the second switching circuit in parallel, wherein the fourth switching circuit has a fourth resistance, is controlled by the second driving signal, and is configured to drive the second switch through the fourth resistance, and wherein the second resistance is greater than the fourth resistance;
wherein the first switching circuit and the fourth switching circuit are further controlled by a first mode signal, the second switching circuit and the third switching circuit are further controlled by a second mode signal, and the first mode signal and the second mode signal are inverted signals to each other.

4. The slew rate control circuit according to claim 3, wherein the first switching circuit comprises:
a first path switch controlled by the first driving signal and the first mode signal, wherein the first path switch is connected between the power wire and the ground wire; and
a first resistive element configured to provide the first resistance and connected to the first path switch in series;
wherein the second switching circuit comprises:
a second path switch controlled by the second driving signal and the second mode signal, wherein the second path switch is connected between the power wire and the ground wire; and
a second resistive element configured to provide the second resistance and connected to the second path switch in series;
wherein the third switching circuit comprises:
a third path switch controlled by the first driving signal and the second mode signal, wherein the third path switch is connected between the power wire and the ground wire; and
a third resistive element configured to provide the third resistance and connected to the third path switch in series; and
wherein the fourth switching circuit comprises:
a fourth path switch controlled by the second driving signal and the first mode signal, wherein the fourth path switch is connected between the power wire and the ground wire; and
a fourth resistive element configured to provide the fourth resistance and connected to the fourth path switch in series.

5. The slew rate control circuit according to claim 4, wherein the first path switch comprises a plurality of fifth switches, the fifth switches are connected to the first resistive element in parallel, and each of the fifth switches is controlled by one of the first driving signal and the first mode signal; the second path switch comprises a plurality of sixth switches, the sixth switches are connected to the second resistive element in parallel, and each of the sixth switches is controlled by one of the second driving signal and the second mode signal; the third path switch comprises a plurality of seventh switches, the seventh switches are connected to the third resistive element in parallel, and each of the seventh switches is controlled by one of the first driving signal and the second mode signal; the fourth path switch comprises a plurality of eighth switches, the eighth switches are connected to the fourth resistive element in parallel, and each of the eighth switches is controlled by one of the second driving signal and the first mode signal.

6. The slew rate control circuit according to claim 3, further comprising:
a third switch, wherein the third switch and the first switching circuit are inversely driven; one of two ends of the third switch is connected to the power wire, the other end of the third switch is connected to the first switching circuit, the third switching circuit, and the control end of the first switch, and the first switch is a low active switch; and
a fourth switch, wherein the fourth switch and the second switching circuit are inversely driven; one of two ends of the fourth switch is connected to the second switching circuit, the fourth switching circuit, and the control end of the second switch, the other end of the fourth switch is connected to the ground wire, and the second switch is a high active switch.

7. The slew rate control circuit according to claim 1, wherein the first switching circuit comprises:
a first path switch controlled by the first driving signal, wherein the first path switch is connected between the power wire and the ground wire; and
a first resistive element configured to provide the first resistance and connected to the first path switch in series; and
wherein the second switching circuit comprises:
a second path switch controlled by the second driving signal, wherein the second path switch is connected between the power wire and the ground wire; and
a second resistive element configured to provide the second resistance and connected to the second path switch in series.

8. A control circuit comprising:
an ancillary signal pad;
at least one high-speed signal pad;
a ground pad;
a power pad;
a signal processing circuit connected to the ancillary signal pad, the ground pad, and the power pad; and
a slew rate control circuit comprising:
a first switch connected between the power pad and one of the at least one high-speed signal pad;
a second switch connected between the one of the at least one high-speed signal pad and the ground pad;
a first switching circuit connected between the power pad and the ground pad, wherein the first switching circuit has a first resistance, is controlled by the first driving signal, and is configured to drive the first switch through the first resistance;
a second switching circuit connected between the power pad and the ground pad, wherein the second switching circuit has a second resistance, is controlled by the second driving signal, and is configured to drive the second switch through the second resistance;
a first grounding capacitor connected to a control end of the first switch and the first switching circuit; and
a second grounding capacitor connected to a control end of the second switch and the second switching circuit.

9. The control circuit according to claim 8, further comprising:
a third switch, wherein the third switch and the first switching circuit are inversely driven; one of two ends of the third switch is connected to the power pad, the other end of the third switch is connected to the first switching circuit and the control end of the first switch, and the first switch is a low active switch; and
a fourth switch, wherein the fourth switch and the second switching circuit are inversely driven; one of two ends of the fourth switch is connected to the second switching circuit and the control end of the second switch, the other end of the fourth switch is connected to the ground pad, and the second switch is a high active switch.

10. The control circuit according to claim 8, further comprising:
a third switching circuit connected to the first switching circuit in parallel, wherein the third switching circuit has a third resistance, is controlled by the first driving signal, and is configured to drive the first switch through the third resistance, and wherein the first resistance is greater than the third resistance; and
a fourth switching circuit connected to the second switching circuit in parallel, wherein the fourth switching circuit has a fourth resistance, is controlled by the second driving signal, and is configured to drive the second switch through the fourth resistance, and wherein the second resistance is greater than the fourth resistance;
wherein the first switching circuit and the fourth switching circuit are further controlled by a first mode signal, the second switching circuit and the third switching circuit are further controlled by a second mode signal, and the first mode signal and the second mode signal are inverted signals to each other.

11. The control circuit according to claim 10, wherein the first switching circuit comprises:
a first path switch controlled by the first driving signal and the first mode signal, wherein the first path switch is connected between the power pad and the ground pad; and
a first resistive element configured to provide the first resistance and connected to the first path switch in series;
wherein the second switching circuit comprises:
a second path switch controlled by the second driving signal and the second mode signal, wherein the second path switch is connected between the power pad and the ground pad; and
a second resistive element configured to provide the second resistance and connected to the second path switch in series;
wherein the third switching circuit comprises:
a third path switch controlled by the first driving signal and the second mode signal, wherein the third path switch is connected between the power pad and the ground pad; and
a third resistive element configured to provide the third resistance and connected to the third path switch in series; and
wherein the fourth switching circuit comprises:
a fourth path switch controlled by the second driving signal and the first mode signal, wherein the fourth path switch is connected between the power pad and the ground pad; and
a fourth resistive element configured to provide the fourth resistance and connected to the fourth path switch in series.

12. The control circuit according to claim 11, wherein the first path switch comprises a plurality of fifth switches, the fifth switches are connected to the first resistive element in parallel, and each of the fifth switches is controlled by one of the first driving signal and the first mode signal; the second path switch comprises a plurality of sixth switches, the sixth switches are connected to the second resistive element in parallel, and each of the sixth switches is controlled by one of the second driving signal and the second mode signal; the third path switch comprises a plurality of seventh switches, the seventh switches are connected to the third resistive element in parallel, and each of the seventh switches is controlled by one of the first driving signal and the second mode signal; the fourth path switch comprises a plurality of eighth switches, the eighth switches are connected to the fourth resistive element in parallel, and each of the eighth switches is controlled by one of the second driving signal and the first mode signal.

13. The control circuit according to claim 10, further comprising:
a third switch, wherein the third switch and the first switching circuit are inversely driven; one of two ends of the third switch is connected to the power pad, the other end of the third switch is connected to the first switching circuit, the third switching circuit, and the control end of the first switch, and the first switch is a low active switch; and
a fourth switch, wherein the fourth switch and the second switching circuit are inversely driven; one of two ends of the fourth switch is connected to the second switching circuit, the fourth switching circuit, and the control end of the second switch, the other end of the fourth switch is connected to the ground pad, and the second switch is a high active switch.

14. The control circuit according to claim 8, wherein the first switching circuit comprises:
a first path switch controlled by the first driving signal, wherein the first path switch is connected between the power pad and the ground pad; and
a first resistive element configured to provide the first resistance and connected to the first path switch in series; and
wherein the second switching circuit comprises:
a second path switch controlled by the second driving signal, wherein the second path switch is connected between the power pad and the ground pad; and
a second resistive element configured to provide the second resistance and connected to the second path switch in series.

15. A connector circuit comprising:
a connector comprising:
a connection head having a mating portion;
at least one high-speed signal pin on the mating portion and fixed on the connection head;
an ancillary signal pin adjacent to the at least one high-speed signal pin, on the mating portion, and fixed on the connection head;
a ground pin on the mating portion and fixed on the connection head; and
a power pin on the mating portion and fixed on the connection head; and
a signal processing circuit connected to the ancillary signal pin, the ground pin, and the power pin; and
a slew rate control circuit comprising:
a first switch connected between the power pin and one of the at least one high-speed signal pin;
a second switch connected between the one of the at least one high-speed signal pin and the ground pin;
a first switching circuit connected between the power pin and the ground pin, wherein the first switching circuit has a first resistance, is controlled by a first driving signal, and is configured to drive the first switch through the first resistance;
a second switching circuit connected between the power pin and the ground pin, wherein the second switching circuit has a second resistance, is controlled by a second driving signal, and is configured to drive the second switch through the second resistance;
a first grounding capacitor connected to a control end of the first switch and the first switching circuit; and
a second grounding capacitor connected to a control end of the second switch and the second switching circuit.

16. The connector circuit according to claim 15, further comprising:
a third switch, wherein the third switch and the first switching circuit are inversely driven; one of two ends of the third switch is connected to the power pin, the other end of the third switch is connected to the first switching circuit and the control end of the first switch, and the first switch is a low active switch; and
a fourth switch, wherein the fourth switch and the second switching circuit are inversely driven; one of two ends of the fourth switch is connected to the second switching circuit and the control end of the second switch, the other end of the fourth switch is connected to the ground pin, and the second switch is a high active switch.

17. The connector circuit according to claim 15, further comprising:
a third switching circuit connected to the first switching circuit in parallel, wherein the third switching circuit has a third resistance, is controlled by the first driving signal, and is configured to drive the first switch through the third resistance, and wherein the first resistance is greater than the third resistance; and
a fourth switching circuit connected to the second switching circuit in parallel, wherein the fourth switching circuit has a fourth resistance, is controlled by the second driving signal, and is configured to drive the second switch through the fourth resistance, and wherein the second resistance is greater than the fourth resistance;
wherein the first switching circuit and the fourth switching circuit are further controlled by a first mode signal, the second switching circuit and the third switching circuit are further controlled by a second mode signal, and the first mode signal and the second mode signal are inverted signals to each other.

18. The connector circuit according to claim 17, wherein the first switching circuit comprises:
a first path switch controlled by the first driving signal and the first mode signal, wherein the first path switch is connected between the power pin and the ground pin; and
a first resistive element configured to provide the first resistance and connected to the first path switch in series;
wherein the second switching circuit comprises:
a second path switch controlled by the second driving signal and the second mode signal, wherein the second path switch is connected between the power pin and the ground pin; and
a second resistive element configured to provide the second resistance and connected to the second path switch in series;
wherein the third switching circuit comprises:
a third path switch controlled by the first driving signal and the second mode signal, wherein the third path switch is connected between the power pin and the ground pin; and
a third resistive element configured to provide the third resistance and connected to the third path switch in series; and
wherein the fourth switching circuit comprises:
a fourth path switch controlled by the second driving signal and the first mode signal, wherein the fourth path switch is connected between the power pin and the ground pin; and
a fourth resistive element configured to provide the fourth resistance and connected to the fourth path switch in series.

19. The connector circuit according to claim 18, wherein the first path switch comprises a plurality of fifth switches, the fifth switches are connected to the first resistive element in parallel, and each of the fifth switches is controlled by one of the first driving signal and the first mode signal; the second path switch comprises a plurality of sixth switches, the sixth switches are connected to the second resistive element in parallel, and each of the sixth switches is controlled by one of the second driving signal and the second mode signal; the third path switch comprises a plurality of seventh switches, the seventh switches are connected to the third resistive element in parallel, and each of the seventh switches is controlled by one of the first driving signal and the second mode signal; the fourth path switch comprises a plurality of eighth switches, the eighth switches are connected to the fourth resistive element in parallel, and each of the eighth switches is controlled by one of the second driving signal and the first mode signal.

20. The connector circuit according to claim 17, further comprising:
a third switch, wherein the third switch and the first switching circuit are inversely driven; one of two ends of the third switch is connected to the power pin, the other end of the third switch is connected to the first switching circuit, the third switching circuit, and the control end of the first switch, and the first switch is a low active switch; and
a fourth switch, wherein the fourth switch and the second switching circuit are inversely driven; one of two ends of the fourth switch is connected to the second switching circuit, the fourth switching circuit, and the control end of the second switch, the other end of the fourth switch is connected to the ground pin, and the second switch is a high active switch.
